(19) United States
(12) Patent Application Publication
(10) Pub. No.: US 2013/0255999 A1
(43) Pub. Date: Oct. 3, 2013

(54) METHOD AND APPARATUS FOR PROVIDING A CONDUCTOR INTERFACE FOR A PHOTOVOLTAIC MODULE

(71) Applicant: FIRST SOLAR, INC., Perrysburg, OH (US)

(72) Inventors: Benyamin Buller, Sylvania, OH (US); Stephen P. Murphy, Perrysburg, OH (US); Raymond Domsic, Gross lle, MI (US); Wenlai Feng, Perrysburg, OH (US)

(73) Assignee: First Solar, Inc., Perrysburg, OH (US)

(21) Appl. No.: 13/847,821

(22) Filed: Mar. 20, 2013

Related U.S. Application Data
(60) Provisional application No. 61/615,970, filed on Mar. 27, 2012.

(51) Int. Cl. H05K 7/06; H01R 43/00; H05K 1/02

(52) U.S. Cl. CPC H05K 7/06; H05K 1/02; H01R 43/00
USPC 174/251; 174/70 R; 29/857

(57) ABSTRACT

Described embodiments provide a conductor interface for a photovoltaic module that includes a raised feature on a bottom surface. Methods of forming such structures are also disclosed, as are photovoltaic modules containing the conductor interface.

### CROSS-REFERENCE TO RELATED APPLICATION

This application claims priority to U.S. Provisional Application No. 61/615,970, filed Mar. 27, 2012, which is hereby fully incorporated by reference.

### TECHNICAL FIELD

The disclosed embodiments relate to a conductor interface used with photovoltaic modules and methods for manufacturing photovoltaic modules having a conductor interface.

### BACKGROUND OF THE INVENTION

Photovoltaic (PV) modules are becoming increasingly popular for providing renewable energy. In order to provide internally generated electricity to outside the module, a conductor interface (also referred to as a cord plate) is typically provided. The conductor interface is attached to the module over an opening in the module and provides an area for external conductors to be electrically connected to internal conductors of the module.

FIG. 1 shows a back perspective view of a conventional photovoltaic module 10. Module 10 is oriented to receive sunlight through a front surface 110 and converts photons in the received sunlight to electricity using internal semiconductors arranged into a plurality of PV cells. The PV cells can be connected in series, parallel, or a combination thereof depending on the desired electrical output from module 10. Brackets 115 connected to module 10 (for example, to peripheral edges of front surface 110 and back surface 140) may be used to fix module 10 to a support structure.

As shown in FIG. 1, external conductors 120, 125 extend from a conductor interface 150 that is affixed to the back surface 140 of module 10.

External conductors 120, 125 provide the electrical current generated by module 10 to external electrical devices or loads. External conductors 120, 125 may be any appropriate wires or cables known in the art, and may include insulating jacket(s) surrounding their conductive core. External conductors 120, 125 may include industry-compliant connectors 130, 135 for ease of installation and interconnection with other elements in a photovoltaic system.

FIG. 2 shows an exploded view of the conductor interface 150, which is affixed over an opening 405 in back surface 140. Conductor interface 150 houses the interconnections of internal conductors 410, 415 that are connected to an internal bussing system of module 10 with external conductors 120, 125. Conductor interface 150 includes a base portion 152 and a cover portion 154. Base portion 152 affixes to back surface 140, and cover portion 154 attaches to base portion 152 after external conductors 120, 125 (FIG. 1) are electrically connected to internal conductors 410, 415.

The internal conductors 410, 415 extend through an opening 405 in back surface 140 of module 10. Internal conductors 410, 415 may be, for example, foil tabs that are connected to an internal bussing system of module 10, such as a positive and a negative bus terminal within module 10. Internal conductors 410, 415 are folded back against back surface 140, such that conductor interface 150 can be placed over the opening 405 and internal conductors 410, 415. An adhesive sealant 420, for example, a dual-sided adhesive foam tape or other adhesive sealant that surrounds the internal conductors 410, 415 and opening 405, is typically used to affix conductor interface 150 to back surface 140.

FIG. 3 shows a bottom surface of a conductor interface 150, which is flat to accommodate adhesive sealant 420 (FIG. 2) and forms a cavity 170. External conductors 120, 125 (FIG. 1) can be inserted into respective wire holes 160, 165 of conductor interface 150, and terminal portions of external conductors 120, 125 are welded, soldered, or otherwise electrically connected to a respective one of internal conductors 410, 415 within cavity 170 after conductor interface 150 is affixed to back surface 140. A potting material or other sealant can then be used to fill cavity 170 within conductor interface 150, in order to prevent moisture and other elements from entering into cavity 170 of conductor interface 150. Cover portion 154 is then attached to base portion 152 after the potting material fills cavity 170.

During the electrical connection of the terminal portions of external conductors 120, 125 to internal conductors 410, 415, wire portions of external conductors 120, 125 are pressed down within cavity 170 and against adhesive sealant 420. For example, wire portions of the external conductors 120, 125 within cavity 170 can be pressed down on adhesive sealant 420 from approximately half the distance between the wire holes 160, 165 and the respective electrical connection points. This can prevent potting material from fully encircling external conductors 120, 125 along this distance, which can result in an imperfect seal or a seal that can weaken over time between the potting material and the remaining portions of the external conductors 120, 125. If the seal between the potting material and these remaining portions is not completely formed or breaks, moisture or other elements may enter conductor interface 150 and affect the electrical connections or enter the opening 405 of module 10.

Accordingly, it is desirable to manufacture a photovoltaic module having a conductor interface that is more thoroughly sealed against moisture ingress.

### BRIEF DESCRIPTION OF THE DRAWINGS

FIG. 1 is a bottom perspective view of a photovoltaic module.

FIG. 2 is an exploded view of a bottom surface of a photovoltaic module.

FIG. 3 is a bottom perspective view of a conventional conductor interface.

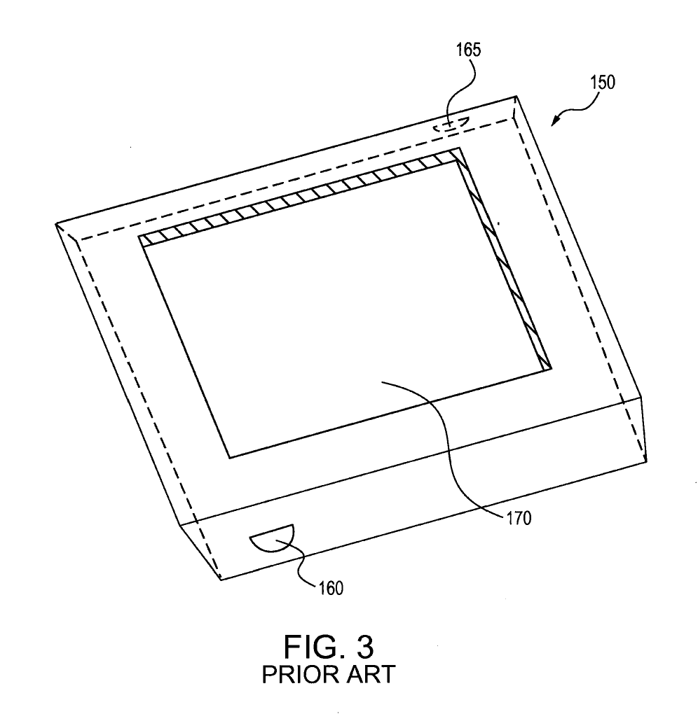

FIG. 4 is a top perspective view of a conductor interface, in accordance with embodiments described herein.

FIG. 5 is a bottom perspective view of a conductor interface, in accordance with embodiments described herein.

FIG. 6 is a bottom perspective view of a conductor interface, in accordance with embodiments described herein.

FIG. 7 is a bottom perspective view of a conductor interface, in accordance with embodiments described herein.

FIG. 8 is a bottom perspective view of a conductor interface, in accordance with embodiments described herein.

FIG. 9 shows a conductor interface mounted on a surface, in accordance with embodiments described herein.

FIG. 10 is a bottom perspective view of a conductor interface, in accordance with embodiments described herein.

FIG. 11 is a bottom perspective view of a conductor interface, in accordance with embodiments described herein.

FIG. 12 is a bottom perspective view of a conductor interface, in accordance with embodiments described herein.

FIG. 13 is a bottom perspective view of a conductor interface, in accordance with embodiments described herein.

### DETAILED DESCRIPTION

In the following detailed description, reference is made to the accompanying drawings which form a part hereof, and which illustrate specific embodiments of the invention. These embodiments are described in sufficient detail to enable those of ordinary skill in the art to make and use them. It is also understood that structural, logical, or procedural changes may be made to the specific embodiments disclosed herein.

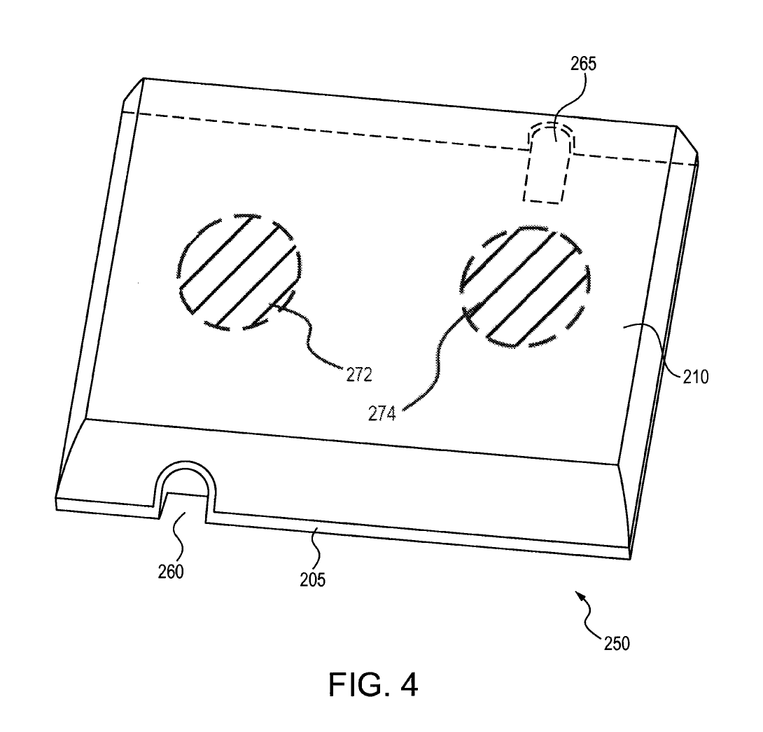

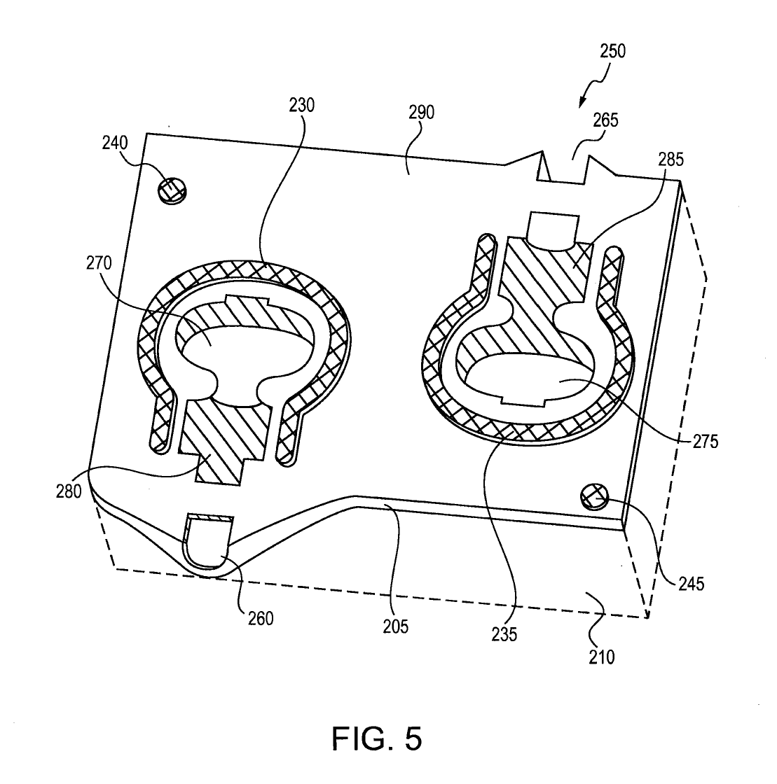

FIGS. 4 and 5 respectively show a top and bottom perspective of an embodiment of a conductor interface 250, which may be used to house interconnections of electrical conductors for a photovoltaic module. Conductor interface 250 includes a base portion 205 and a top portion 210. Base portion 205 can be mounted adjacent to a mounting surface, such as a back surface 140 of a photovoltaic module 10. Top portion 210 connects with base portion 205 and defines a pair of cavities 270, 275 (FIG. 5) within conductor interface 250 for respectively housing electrical interconnections between module internal and external conductors. Top portion 210 may include openings 272, 274 exposing the cavities 270, 275 within conductor interface 250. Cavities 270, 275, respectively, provide areas that allow electrical connection of terminal portions 122, 127 of external conductors 120, 125 with internal module conductors 410, 415.

Base portion 205 and top portion 210 may be a single piece, or may be two separate connectable pieces capable of being connected using interlocking connectors (e.g., a snap connector), an adhesive, or other techniques known in the art. Top portion 210 includes downwardly extending sidewalls that meet and interconnect with upwardly extending sidewalls of base portion 205. In other embodiments, top portion 210 may be a flat plate configured to interconnect with the upwardly extending sidewalls of base portion 205.

Conductor interface 250 may be formed from plastic, metal, or other appropriate materials. For example, conductor interface 250 may be formed from a plastic or polycarbonate material shaped through an injection molding process.

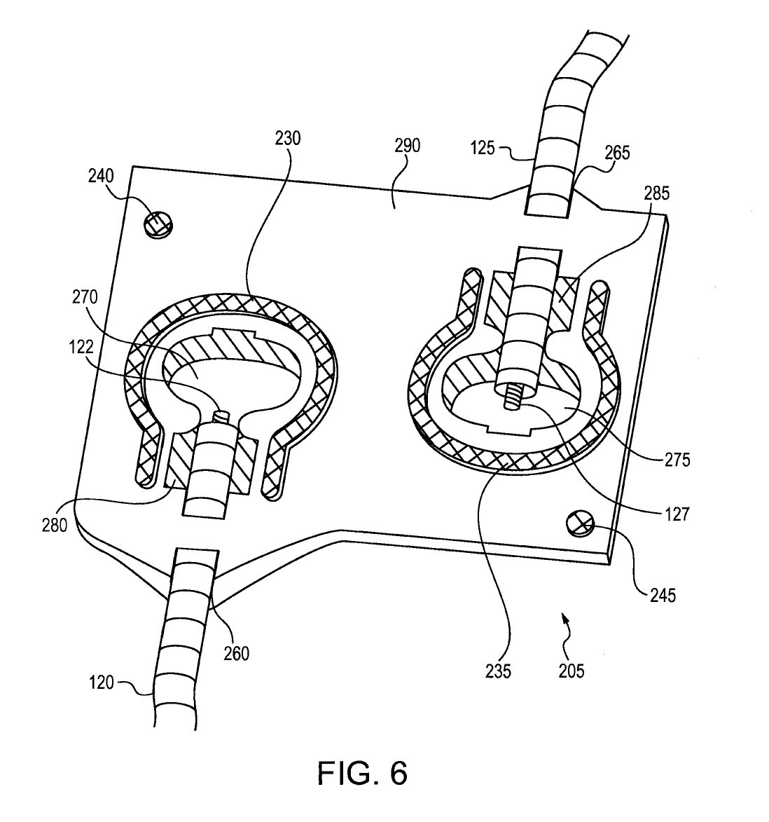

Conductor interface 250 includes wire holes 260, 265, through which external conductors 120, 125 (FIG. 6) can respectively be inserted. A silhouette of wire hole 265 is shown because it is on the backside of conductor interface 250 in the perspective shown in FIG. 4. Although two wire holes 260, 265 are shown in FIG. 4, it should be understood that a conductor interface 250 may have fewer or more wire holes to accommodate the number of electrical connections that need to be made to internal conductors of a module 10.

FIG. 6 shows a bottom perspective of base portion 205 with external conductors 120, 125 inserted into wire holes 260, 265, respectively. As noted above with respect to FIG. 5, base portion 205 can be connected to top portion 210, or base portion 205 and top portion 210 can be formed as a single piece.

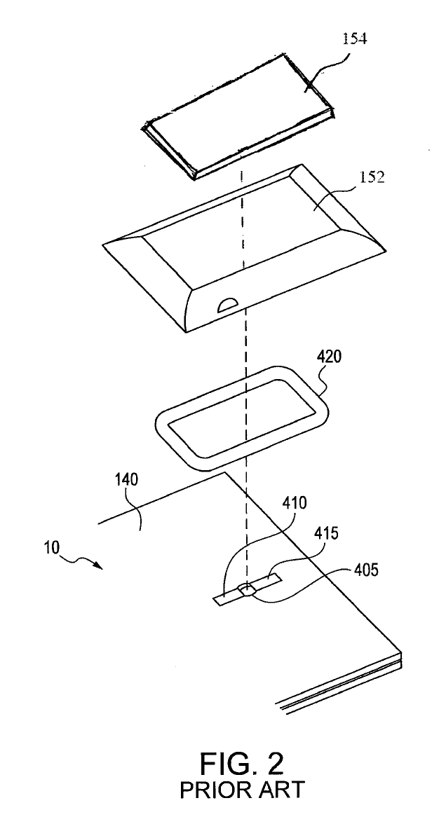

The bottom surface 290 of base portion 205 includes respective connection cavities 270, 275 and wire cavities 280, 285. As shown in FIG. 6, an external conductor 120 traversing wire hole 260 extends through wire cavity 280 into connection cavity 270. An external conductor 125 traversing wire hole 265 extends through wire cavity 285 into connection cavity 275. External conductors 120, 125 include respective terminal portions 122, 127, which can be electrically connected to respective internal conductors 410, 415 of photovoltaic module 10 (FIG. 2) within the respective connection cavities 270, 275.

Wire cavities 280, 285 surround wire portions of the external conductors 120, 125 inserted into respective wire holes 260, 265. Wire cavities 280, 285 are enclosed above and open below the respective locations for the wire portions of external conductors 120, 125. Connection cavities 270, 275 house the terminal portions 122, 127 of external conductors 120, 125, which include the exposed electrically conductive material used to form electrical connections, such as when soldered to internal conductors 410, 415 of a photovoltaic module 10 (FIG. 2). Connection cavities 270, 275 may be enclosed above the locations for the terminal portions 122, 127 by a separate top portion 210 that is attached after electrical connections within connection cavities 270, 275 are completed. In other embodiments, connection cavities 270, 275 may be exposed through openings 272, 274 of top portion 210 (FIG. 4) to permit electrical connection of terminal portions 122, 127 to internal conductors 410, 415 (FIG. 2) after top portion 210 is attached or if top portion 210 and base portion 205 are formed as a single piece.

The bottom surface 290 of base portion 205 includes a raised feature 230 partially surrounding connection cavity 270 and wire cavity 280, and a raised feature 235 partially surrounding connection cavity 275 and wire cavity 285. These raised features 230, 235 act as standoffs and enable the use of a fluid adhesive, such as a glue or paste, to be applied between base portion 205 and a module 10 for bonding conductor interface 250 to the module 10.

The fluid adhesive may be, for example, a water, silicone, urethane, or epoxy-based adhesive. The fluid adhesive may be, for example, a one-part adhesive that cures through exposure to air, or may be a two-part adhesive including a resin and a catalyst for stimulating curing of the resin. The fluid adhesive may be selected to have a high adhesive strength to glass and polycarbonate and a high intrinsic tensile strength. For example, the fluid adhesive may have a tensile strength rating (ASTM D412) that is greater than approximately 1.5 MPa, and an adhesive strength to bottom surface 290 of conductor interface 250 and to module 10 that is greater than the tensile strength. The fluid adhesive may be an adhesive capable of withstanding damp heat conditions and having a high flammability rating. For example, the fluid adhesive may be a one or two-part non-slumping paste having a UL Flammability Rating and a Relative Thermal Index greater than or equal to approximately 105° C. In addition, the fluid adhesive may also be resistive to the flow of electricity. For example, the fluid adhesive may have a volume resistivity that is greater than approximately 1×10¹³ ohm*cm and a dielectric strength that is greater than 15 Kv/mm.

The fluid adhesive has a fluid consistency. For example, the fluid adhesive may have a viscosity in a range of approximately 10,000 centiPoise (cP) to approximately 200,000 cP at room temperature. A relatively fluid adhesive can provide higher bond strength between the conductor interface 250 and a photovoltaic module than is achieved with a typical solid adhesive, such as a foam tape.

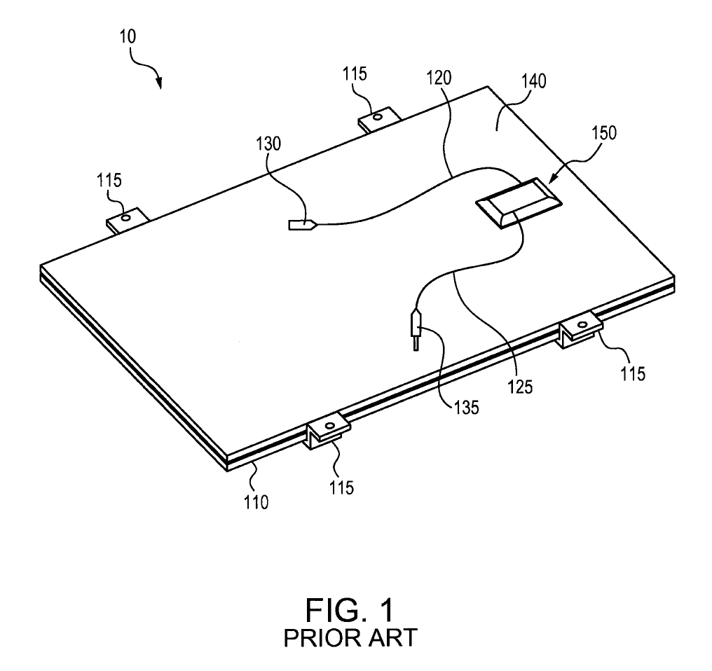

Raised features 230, 235 maintain a fixed gap between bottom surface 290 of base portion 205 and the module back surface 140 to which conductor interface 250 is bonded (FIG. 1). For example, raised features 230, 235 may both have a height of approximately 0.8 mm.

Raised features 230, 235 may be spaced approximately 2 mm away from the respective connection cavities 270, 275 and wire cavities 280, 285. The ends of raised features 230, 235 extend partially but not completely to the edge of bottom surface 290, to allow for a layer of adhesive material to be applied between raised features 230, 235 and the edges of bottom surface 290. For example, raised feature 230 may extend to approximately 11 mm from the edge of bottom surface 290 in which wire hole 260 is located, and raised feature 235 may extend to approximately 11 mm from the edge of bottom surface 290 in which wire hole 265 is located. Raised features 230, 235 may have substantially uniform or varying widths along their respective lengths. For example, raised features 230, 235 may be approximately 1.5 mm wide along their lengths.

Raised features 230, 235, in addition to providing a fixed space between bottom surface 290 the back surface 140 of photovoltaic module 10 (FIG. 1) for a fluid adhesive material to occupy, also prevents the fluid adhesive from leaking into connection cavities 270, 275 or wire cavities 280, 285. Adhesive leaking into connection cavities 270, 275 can interfere with the electrical connection of external conductors 120, 125 to internal conductors 410, 415 (FIG. 2). Adhesive leaking into wire cavities 280, 285 may also come into contact with the external conductors 120, 125 as they are inserted into the conductor interface 250, resulting in the adhesive being transferred on the wires into the connection cavities 270, 275.

Raised features 230, 235 also ensure that there is space between external conductors 120, 125 and the back surface 140 of the module 10 to which conductor interface 250 is bonded (FIG. 1). This allows potting material used to fill conductor interface 250 to completely surround external conductors 120, 125. For example, longer sections of external conductors 120, 125 can be completely surrounded by potting material, providing a more robust seal to prevent moisture ingress and electrical leakage. Furthermore, the open space beneath internal conductors 120, 125 that is provided by the raised features 230, 235 ensures that potting material also contacts the surface of module 10 to which conductor interface 250 is bonded, thereby creating an even stronger and better sealed bond between conductor interface 250 and the module surface. In addition, the fixed space provided by raised features 230, 235 creates a predetermined volume to be filled by the potting material, such as the volume within cavities 270, 275, 280, 285 and between these cavities and the back surface 140 of the module 10, which helps to ensure complete potting material fillage and facilitates automation of the manufacturing process by allowing a fixed amount of potting material to be used.

As shown in FIGS. 5 and 6, base portion 205 may also include raised features 240, 245 at opposing corners of bottom surface 290 to provide greater stability when conductor interface 250 is mounted to a module 10. Raised features 240, 245 may be approximately the same height as raised features 230, 235. For example, raised features 230, 235, 240, 245 may all have a height of approximately 0.8 mm. Raised features 240, 245 may have a circular surface area, as shown in FIGS. 5 and 6, or have other shapes, such as an elliptical or polygon shape. In one example, raised features 240, 245 may have circular surface areas with radii of approximately 0.25 mm. Raised features 240, 245 are located at a distance from the opposing corners of bottom surface 290 sufficient to allow for a layer of adhesive material to be applied between raised features 240, 245 and the edges of bottom surface 290. For example, raised features 240, 245 may be located in a range of at least 5 to 10 mm from the opposing corners of bottom surface 290.

One or more of raised features 230, 235, 240, 245 may also have a secondary adhesive material, such as a quick bonding hot or room temperature adhesive, a pressure-sensitive adhesive material, or a dual-sided foam tape, affixed to its surface. The secondary adhesive on one or more of raised features 230, 235, 240, 245 can be used to hold base portion 205 in place on a module to which it is mounted while the fluid adhesive cures and solidifies.

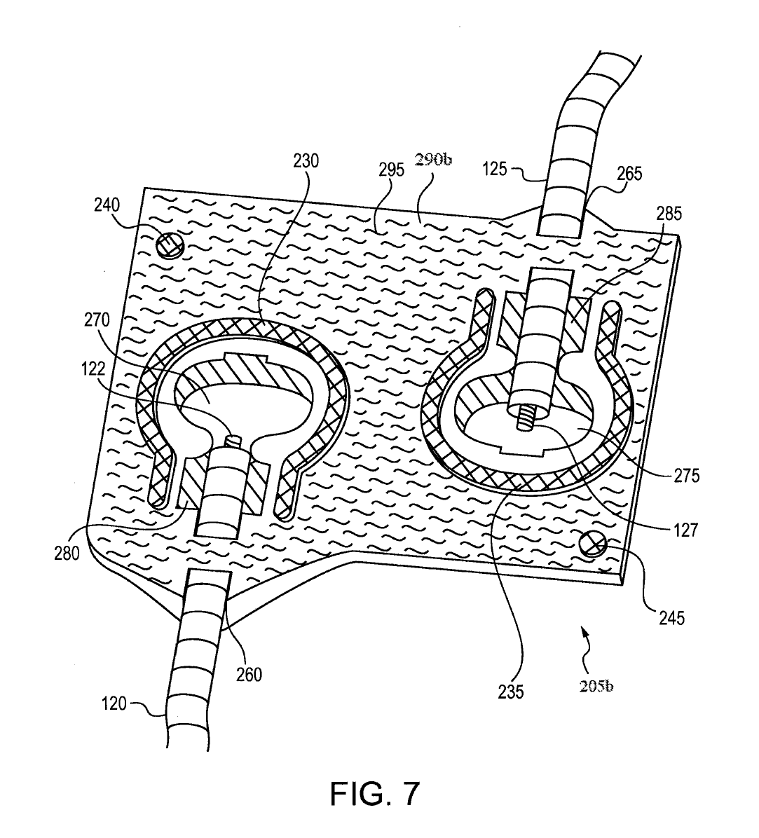

FIG. 7 shows a bottom perspective of another embodiment of a base portion 205b for conductor interface 250. Base portion 205b includes similar features as base portion 205 discussed in connection with FIGS. 5-6, including raised features 230, 235, 240, 245. In addition, bottom surface 290b of base portion 205b includes a surface texture 295 to enhance the bond strength of the fluid adhesive applied to bottom surface 290b. The surface texture 295 may be, for example, a random surface character or other roughness character having a depth in a range of 25 μm to 100 μm, and can be applied by the injection molding process during the formation of conductor interface 250. The surface texture 295 may be applied to substantially all of bottom surface 290b, or to a portion of bottom surface 290b.

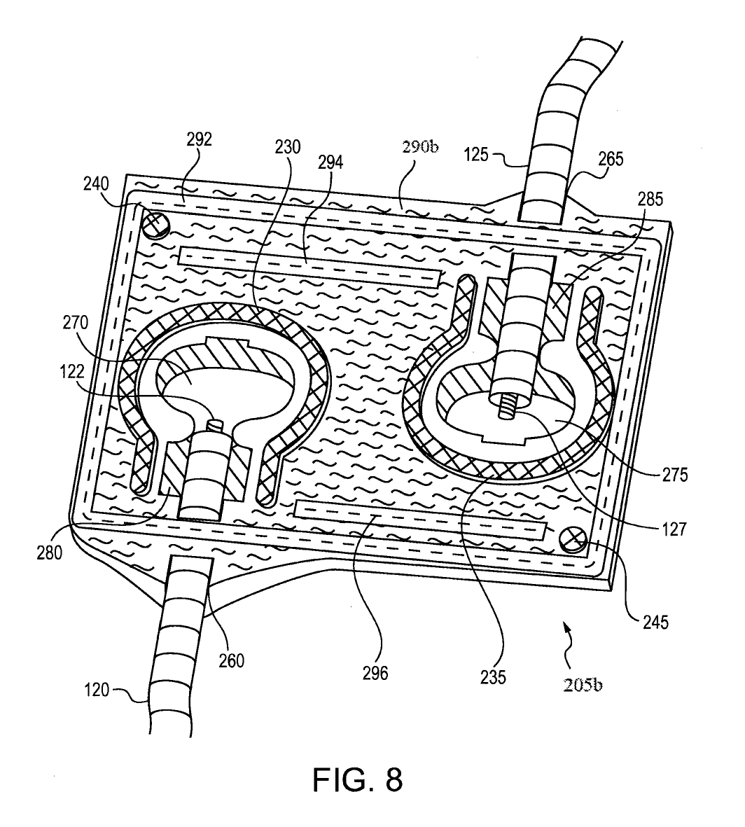

FIG. 8 shows a bottom perspective of base portion 205b with fluid adhesive 292 applied to bottom surface 290b. As described above, fluid adhesive 292 may be a non-slumping paste with a fluid consistency. Fluid adhesive 292 may be, for example, a water, silicone, urethane, or epoxy-based one-part or two-part adhesive, which may be selected to have a high adhesive strength to glass and polycarbonate and a high intrinsic tensile strength, capable of withstanding damp heat conditions, having a high flammability rating, and electrically resistive.

The fluid adhesive 292 may be applied covering substantially all of bottom surface 290b outside of raised features 230, 235, or alternatively may be applied covering a portion of bottom surface 290b. For example, as shown in FIG. 8, a layer of fluid adhesive 292 may be applied surrounding the perimeter of bottom surface 290b. The layer of fluid adhesive 292 may be applied in a pattern with a diameter in a range of approximately 5 mm to 10 mm. When applied, the fluid adhesive will typically expand to cover a larger portion of bottom surface 290b, and therefore should be applied with some distance, for example, 2 mm, from the edge of bottom surface 290b to prevent adhesive from spreading beyond bottom surface 290b and/or under wire holes 260, 265. If fluid adhesive 292 is a two-part adhesive, a resin portion may be applied first, and then a catalyst portion applied to the resin portion.

Multiple layers of fluid adhesive may be applied to bottom surface 290b. For example, in addition to a layer of fluid adhesive 292 applied surrounding the perimeter of bottom surface 290, addition layers of fluid adhesive 294, 296 may be applied on inner areas of bottom surface 290b, such as layer 294 applied between raised feature 235 and raised feature 240, and layer 296 applied between raised feature 230 and raised feature 245. The layers of fluid adhesive 292, 294, 296 may be applied using a hot or cold automated applicator or dispenser, through a manual application process, or through other known techniques. Similar arrangements for fluid adhesive 292, 294, 296 may also be applied to bottom surface 290 of base portion 205 (FIGS. 5-6).

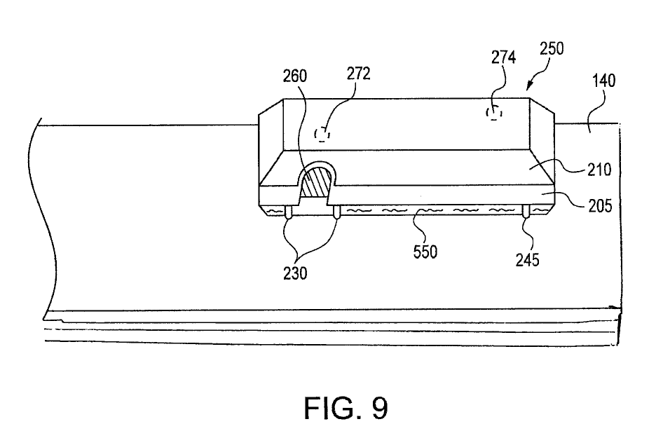

FIG. 9 shows a conductor interface 250 affixed to back surface 140 of a photovoltaic module 10 above an opening 405 exposing one or more internal conductors 410, 415 (FIG. 2). A secondary adhesive on the surface area of one or more of the raised features 230, 235, 240, 245 (FIG. 5) may be used to affix conductor interface 250 to surface 500 while a fluid adhesive bond is formed with the adhesive provided between the bottom surface 290 of conductor interface 250. Conductor interface 250 includes base portion 205 and top portion 210, although it should be understood that conductor interface 250 could instead include base portion 205b discussed in connection with FIGS. 7-8.

As shown in FIG. 9, fluid adhesive 550 (e.g., from adhesive layers 292, 294, 296 of FIG. 8) fills the space between back surface 140 and conductor interface 250 that is maintained by raised features 230, 235, 240, 245 (FIGS. 5-8). The applied fluid adhesive is cured to form a bond between conductor interface 250 and back surface 140, such as by allowing it to harden through exposure to air or other elements, applying a heat or cooling source, and/or other known types of curing treatments. Raised features 230, 235 prevent fluid adhesive from entering connection cavities 270, 275 and wire cavities 280, 285.

After conductor interface 250 is affixed to back surface 140, external conductors 120, 125 (FIG. 6) may be inserted into wire holes 260, 265, where they can be electrically connected to internal conductors 410, 415 (FIG. 2) of the photovoltaic module 10, for example by welding or soldering the terminal portions 122, 127 of external conductors 120, 125 to internal conductors 410, 415 prior to affixing cover portion 210 to base portion 205, or by welding or soldering the terminal portions 122, 127 to internal conductors 410, 415 through openings 272, 274 when base portion 205 and cover portion 210 are formed as a single piece. Alternatively, external conductors 120, 125 may be inserted into wire holes 260, 265 and electrically connected to internal conductors 410, 415 prior to affixing conductor interface 250 to back surface 140.

After electrical connection is made between the external conductors 120, 124 and internal conductors 410, 415, connection cavities 270, 275 and wire cavities 280, 285 are then filled with potting material, for example through openings 272, 274 or wire holes 260, 265. Together with fluid adhesive 550, the potting material filling the cavities of conductor interface 250 electrically isolates the electrical connections and prevents moisture from entering into conductor interface 250. Because raised features 230, 235 form a fixed volume surrounding external conductors 120, 125, a known amount of potting material can be used to fill the cavities 270, 275, 280, 285. In addition, raised features 230, 235 allow potting material to completely surround portions of internal conductors 120, 125 within conductor interface 250.

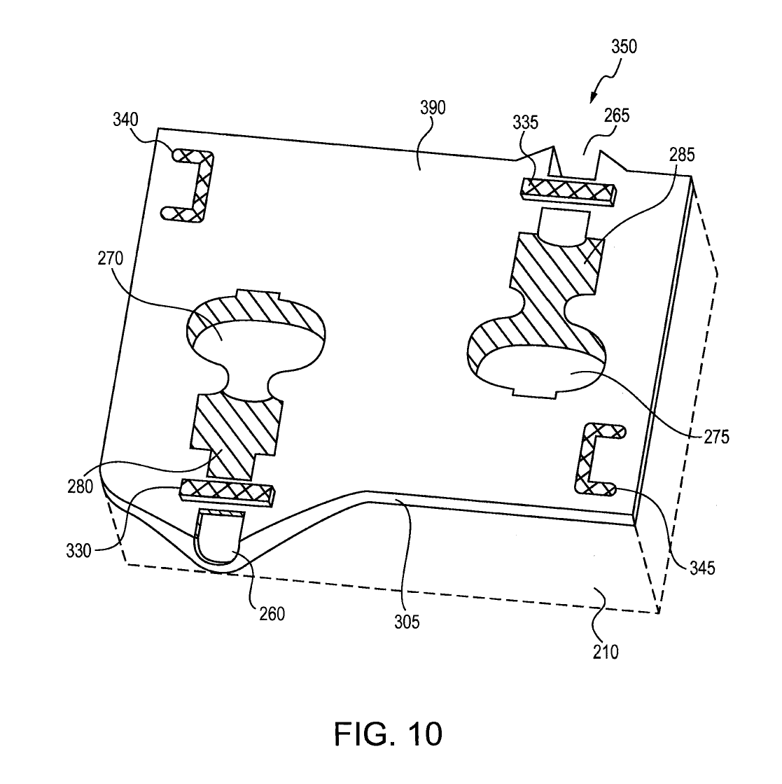

FIG. 10 shows a bottom perspective of another embodiment of a conductor interface 350. Conductor interface 350 can be mounted adjacent to back surface 140 of a photovoltaic module 10 (FIG. 1). Conductor interface 350 includes a base portion 305 and a top portion 210. Base portion 305 can be mounted adjacent to a mounting surface, such as a back surface 140 of a photovoltaic module 10. Top portion 210 has similar features as the top portion 210 discussed above in connection with FIG. 5. Conductor interface 350 may be formed from plastic, metal, or other appropriate materials. For example, conductor interface 350 may be formed from a plastic or polycarbonate material shaped through an injection molding process.

Conductor interface 350 includes wire holes 260, 265 through which external conductors 120, 125 (FIG. 6) can be inserted. Although two wire holes 260, 265 are shown in FIG. 10, it should be understood that a conductor interface 350 may have fewer or greater wire holes to accommodate the number of desired electrical connections.

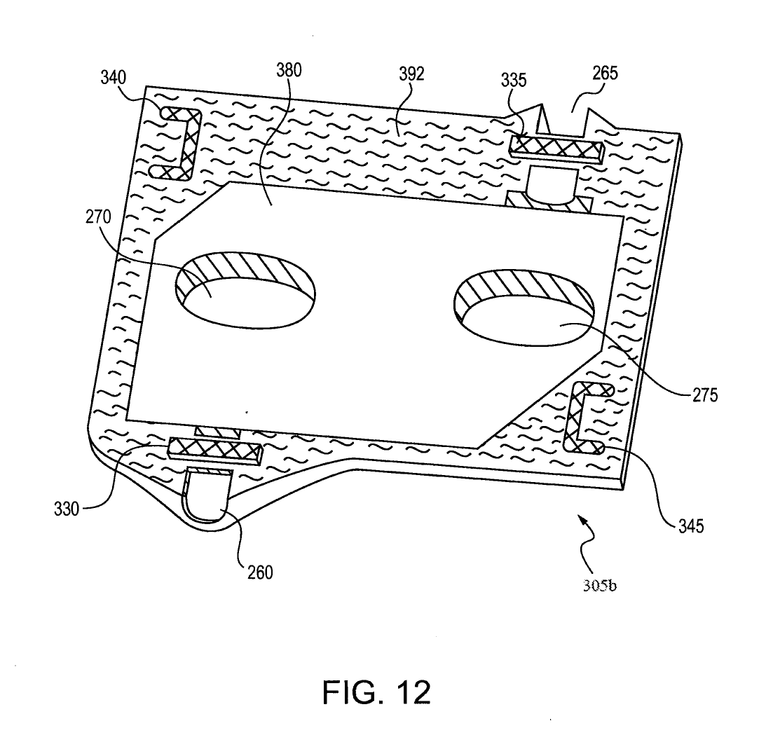

The bottom surface 390 of conductor interface 350 includes respective connection cavities 270, 275 and wire cavities 280, 285, which have similar features as connection cavities 270, 275 and wire cavities 280, 285 discussed in connection with FIGS. 5-9. Bottom surface 390 of conductor interface 350 includes a raised feature 330 at an outer end of wire cavity 280, and a raised feature 335 at an outer end of wire cavity 285. As discussed further below, raised features 330, 335 are arranged to, accommodate a secondary adhesive 380 (FIG. 12), such as a dual-sided tape, that can be used to affix conductor interface 350 to a module surface while a fluid adhesive, such as a glue or paste, forms a bond between conductor interface 350 and the back surface 140.

Raised features 330, 335 may have similar heights and widths as raised features 230, 235 discussed above in connection with FIGS. 5-9. For example, raised features 330, 335 may both have a height of approximately 0.8 mm, and may be approximately 1.5 mm wide along their lengths. Raised features 330, 335 may be spaced approximately 2 mm away from the respective wire cavities 280, 285.

Raised features 330, 335 provide a fixed space between bottom surface 390 of conductor interface 350 and a back surface 140 to which it is to be bonded. The fixed space forms a cavity for fluid adhesive material to bond conductor interface 350 to back surface 140. Raised features 330, 335 also help prevent the fluid adhesive from leaking into wire cavities 280, 285. As discussed in connection with FIGS. 5-9, raised features 330, 335 also ensure that there is space between external conductors 120, 125 inserted into wire holes 260, 265 and the back surface 140, allowing potting material to completely surround external conductors 120, 125. Furthermore, the open space beneath external conductors 120, 125 allows the potting material to also contact the back surface 140.

Conductor interface 350 may also include raised features 340, 345 at opposing corners of bottom surface 390 to provide added stability when conductor interface 350 is mounted to a module 10. Raised features 340, 345 may be approximately the same height and width as raised features 330, 335. Raised features 340, 345 may have a horseshoe or other polygonal shape, or may have a circular surface area similar to raised features 240, 245 discussed in connection with FIGS. 5 and 6. Raised features 340, 345 may be located at a distance from the opposing corners of bottom surface 390 sufficient to allow for a layer of adhesive material to be applied between raised features 340, 345 and the edges of bottom surface 390, or may be located at a lateral distance from wire and connection cavities 270, 275, 280, 285 sufficient to allow for a layer of adhesive material to be applied between the cavities 270, 280 and raised feature 345, and for a layer of adhesive material to be applied between cavities 275, 285 and raised feature 340.

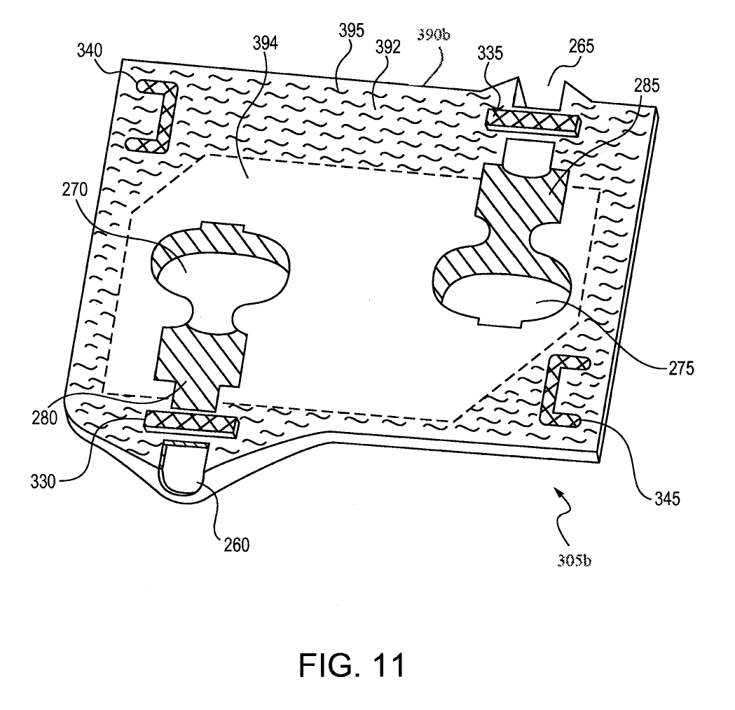

FIG. 11 shows a bottom perspective of another embodiment of a base portion 305b for conductor interface 350. Base portion 305b includes similar features as base portion 305 discussed in connection with FIG. 10, including raised features 330, 335, 340, 345. In addition, bottom surface 390b of base portion 305b includes an area 392 in which a fluid adhesive can be applied, and an area 394 in which a secondary adhesive material 380 (FIG. 12), such as a pressure-sensitive adhesive material or a dual-sided foam tape, can be affixed to bottom surface 390. Area 392 in which the viscous material can be applied may have a surface texture 395 to enhance the bond strength of the fluid adhesive, such as a random surface character or other roughness character having a depth in a range of 25 μm to 100 p.m. Area 394 may be substantially flat to accommodate a dual-sided foam tape or pressure-sensitive adhesive.

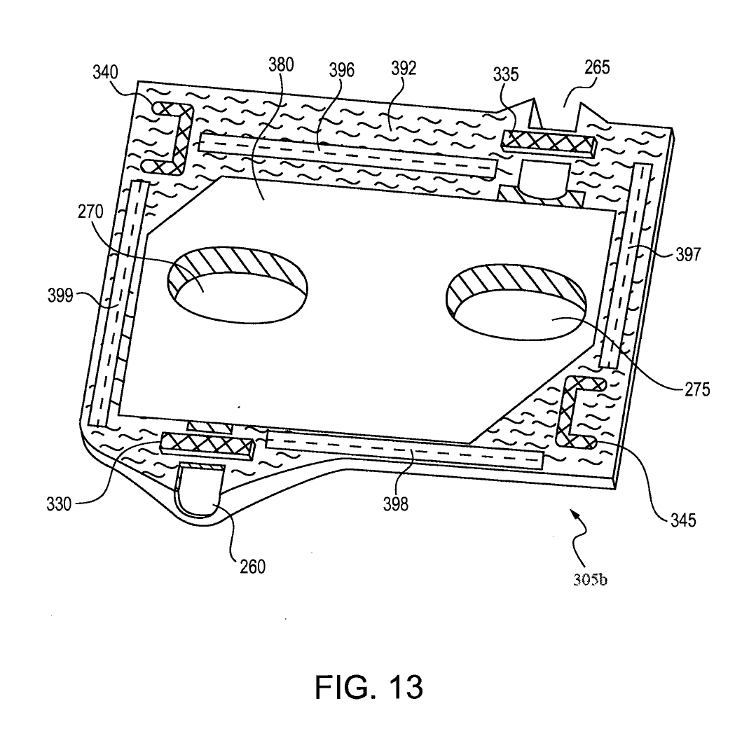

FIG. 12 shows a bottom perspective of base portion 305b with secondary adhesive 380 applied over area 394 (FIG. 11) of bottom surface 390b. As discussed above, secondary adhesive 380 may be, for example, a dual-sided foam tape or a pressure-sensitive adhesive. Secondary adhesive 380 can be used to hold conductor interface 350 in place on a back surface 140 to which it is mounted while the fluid adhesive 396, 397, 398, 399 (FIG. 13) cures and solidifies. Secondary adhesive 380 has a thickness that is approximately the same or greater than the height of raised features 330, 335, to permit secondary adhesive 380 to make contact with the back surface 140 of a module 10, and to serve as a barrier to prevent the fluid adhesive from entering connection cavities 270, 275 and wire cavities 280, 285. Secondary adhesive 380 includes openings to expose connection cavities 270, 275, in order to permit electrical connection of external conductors 120, 125 (FIG. 6) inserted into wire openings 260, 265 with respective internal conductors 410, 415 (FIG. 2). Secondary adhesive 380 is shaped to permit a fluid adhesive to be applied on area 392 of bottom surface 390b.

FIG. 13 shows a bottom perspective of base portion 305b with a secondary adhesive 380 applied to area 394 (FIG. 11) of bottom surface 390b and fluid adhesive applied to area 392 of bottom surface 390b. For example, layers of fluid adhesive 396, 397, 398, 399 may be applied surrounding the perimeter of bottom surface 390b. The layers of fluid adhesive 396-399 may be, for example, applied with a width in a range of approximately 5 mm to 10 mm. When applied to back surface 140, the fluid adhesive will typically expand to cover a larger portion of area 392, and therefore should be applied with some distance, for example, 2 mm, from the edge of bottom surface 390b.

Details of one or more embodiments are set forth in the accompanying drawings and description. Other features, objects, and advantages will be apparent from the description, drawings, and claims. It should also be understood that the appended drawings are not necessarily to scale, presenting a somewhat simplified representation of various features and basic principles of the invention. Although a number of embodiments of the invention have been described, it will be understood that various modifications may be made without departing from the spirit and scope of the invention.

What is claimed as new and desired to be protected by Letters Patent of the United States is:

1. A conductor interface comprising:
at least one wire hole configured to receive an external conductor; and
a bottom surface comprising:
a wire cavity configured to expose a wire portion of the received external conductor;
a connection cavity configured to expose a terminal portion of said received external conductor; and
a raised feature proximate said wire cavity, wherein said raised feature is configured to provide a space between said bottom surface and a surface to which said conductor interface is to be mounted.

2. The conductor interface of claim 1, wherein said raised feature extends at least partially around a perimeter of said connection cavity and said wire cavity.

3. The conductor interface of claim 1, further comprising:
a second wire hole configured to receive a second external conductor;
a second wire cavity configured to expose a wire portion of a second received external conductor and a second connection cavity configured to expose a terminal portion of said second external conductor; and
a second raised feature located between said second wire hole and said second wire cavity.

4. The conductor interface of claim 3, wherein the second raised feature extends at least partially around a perimeter of said second connection cavity and said second wire cavity.

5. The conductor interface of claim 4, further comprising third and fourth raised features at opposing corners of said bottom surface.

6. The conductor interface of claim 1, wherein said raised feature is located between said wire hole and said wire cavity.

7. The conductor interface of claim 1, wherein said wire cavity is arranged between said wire hole and said connection cavity.

8. The conductor interface of claim 1, wherein said raised feature comprises an adhesive on its surface configured to affix said conductor interface to a surface.

9. The conductor interface of claim 8, wherein said adhesive comprises at least one of:
a quick bonding hot adhesive;
a quick bonding room temperature adhesive;
a pressure-sensitive adhesive; and
a dual-sided foam tape.

10. The conductor interface of claim 1, wherein said bottom surface comprises a surface texture.

11. The conductor interface of claim 10, wherein substantially the entire area of said bottom surface that does not include raised features comprises said surface texture.

12. The conductor interface of claim 10, wherein said bottom surface comprises a first area with said surface texture, and a second area with a substantially flat surface.

13. The conductor interface of claim 12, wherein said second area comprises an area between said wire and connection cavities and said raised feature.

14. The conductor interface of claim 12, wherein said first area surrounds said second area.

15. The conductor interface of claim 12, further comprising at least one of a pressure-sensitive adhesive and a dual-sided foam tape located in said second area.

16. The conductor interface of claim 1, further comprising:
a base portion including said at least one wire hole and said bottom surface; and
a top portion covering said base portion.

17. The conductor interface of claim 16, wherein said base portion and said top portion are separate pieces configured to connect to one another.

18. The conductor interface of claim 16, wherein said base portion and said top portion are formed as a single piece.

19. The conductor interface of claim 16, wherein said top portion comprises an opening exposing said connection cavity.

20. The conductor interface of claim 1, wherein said raised feature is configured to maintain a gap under said received external conductor between said bottom surface and said surface to which said conductor interface is to be mounted.

21. The conductor interface of claim 1, further comprising a layer of adhesive on said bottom surface.

22. The conductor interface of claim 20, wherein said layer of adhesive at least partially surrounds a perimeter of said bottom surface.

23. The conductor interface of claim 21, further comprising another layer of adhesive in an internal area of said bottom surface.

24. A photovoltaic module comprising:
a plurality of photovoltaic cells formed between a front surface and a back surface;
an internal conductor electrically connected to said photovoltaic cells protruding from an opening in said back surface; and
a conductor interface affixed to said back surface over said opening, said conductor interface comprising:
a wire hole;
an external conductor inserted into said wire hole;
a wire cavity encompassing a wire portion of said external conductor and exposing said wire portion at a bottom surface of said conductor interface;
a connection cavity encompassing a terminal portion of said external conductor and exposing said terminal portion at the bottom surface of said conductor interface; and
a raised feature proximate said wire cavity on said bottom surface, wherein said raised feature provides a space between said bottom surface and said back surface.

25. The photovoltaic module of claim 24, wherein said raised feature extends at least partially around a perimeter of said connection cavity and said wire cavity.

26. The photovoltaic module of claim 24, said conductor interface further comprising:
a second wire hole;
a second external conductor inserted into said second wire hole;
a second wire cavity encompassing a wire portion of said second external conductor and exposing said wire portion at said bottom surface of said conductor interface;
a second connection cavity encompassing a terminal portion of said second external conductor and exposing said terminal portion at said bottom surface of said conductor interface; and
a second raised feature located between said second wire hole and said second wire cavity on said bottom surface of said conductor interface, wherein said raised feature and said second raised feature provide said space between said bottom surface and said back surface.

27. The photovoltaic module of claim 26, further comprising third and fourth raised features at opposing corners of said bottom surface of said conductor interface.

28. The photovoltaic module of claim 24, wherein said raised feature is located between said wire hole and said wire cavity on said bottom surface of said conductor interface.

29. The photovoltaic module of claim 24, further comprising an adhesive bonding said bottom surface of said conductor interface to said back surface of said photovoltaic module.

30. The photovoltaic module of claim 29, further comprising a second adhesive bonding said conductor interface to said back surface of said photovoltaic module.

31. The photovoltaic module of claim 30, wherein said second adhesive is located on said raised feature.

32. The photovoltaic module of claim 30, wherein said second adhesive is located on said bottom surface of said conductor interface.

33. The photovoltaic module of claim 24, wherein said bottom surface comprises a surface texture.

34. The photovoltaic module of claim 33, wherein said bottom surface comprises a first area with said surface texture and a second area with a substantially flat surface, wherein a first adhesive is located substantially in said first area and a second adhesive is located substantially in said second area.

35. The photovoltaic module of claim 34, wherein said first area substantially surrounds said second area on said bottom surface of said conductor interface.

36. A method of manufacturing a photovoltaic module comprising:
providing a module comprising a plurality of photovoltaic cells between a front surface and a back surface and an opening in said back surface exposing an internal conductor electrically connected to said photovoltaic cells;
providing a conductor interface, wherein said conductor interface comprises:
a wire hole configured to receive an external conductor;
a wire cavity configured to expose a wire portion of a received external conductor at a bottom surface of said conductor interface;
a connection cavity configured to expose a terminal portion of said received external conductor at said bottom surface of said conductor interface; and
a raised feature proximate said wire cavity to provide a space between said bottom surface and a surface to which said conductor interface is mounted; and
affixing said conductor interface to said back surface of said module using a fluid adhesive.

37. The method of claim 36, wherein affixing said conductor interface to said back surface of said photovoltaic module further comprises:
applying said adhesive to said bottom surface of said conductor interface; and
placing said conductor interface on said back surface of said photovoltaic module such that said raised feature rests on said bottom surface and said adhesive fills a space between said back surface and said bottom surface of said conductor interface.

38. The method of claim 37, wherein said adhesive is a fluid adhesive which must be cured, the method further comprising affixing said conductor interface to said back surface of said photovoltaic module using a second adhesive before said fluid adhesive is cured.

39. The method of claim 38, further comprising:
affixing said second adhesive to a substantially flat portion of said bottom surface of said conductor interface; and
applying said fluid adhesive to a textured portion of said bottom surface.

40. The method of claim 39, wherein said second adhesive is located on said raised feature.

41. The method of claim 37, wherein applying said adhesive to said bottom surface of said conductor interface comprises applying said adhesive to a perimeter area of said bottom surface.

42. The method of claim 41, wherein applying said adhesive to said bottom surface of said conductor interface further comprises applying said adhesive to an internal area of said bottom surface.

43. The method of claim 36, wherein said conductor interface further comprises:
a base portion comprising said bottom surface and said raised feature; and
a top portion configured to enclose said base portion.

44. The method of claim 43, wherein said base portion and said top portion are a single piece.

45. The method of claim 43, wherein said base portion is configured to connect to said top portion.

46. The method of claim 44, further comprising:
inserting an external conductor into said wire hole such that a terminal portion of said external conductor traverses said wire cavity and said connection cavity;
electrically connecting said terminal portion of said external conductor to said internal conductor of said module within said connection cavity through an opening in said top portion exposing said connection cavity; and
filling said wire cavity and said connection cavity with potting material through said opening in said top portion, such that said potting material surrounds said wire portion of said external conductor.

47. The method of claim 45, further comprising:
inserting an external conductor into said wire hole such that a terminal portion of said external conductor traverses said wire cavity and said connection cavity;
electrically connecting said terminal portion of said external conductor to said internal conductor of said module within said connection cavity;
filling said wire cavity and said connection cavity with potting material such that said potting material surrounds said wire portion of said external conductor; and
connecting said top portion to said bottom portion.
